(19) United States
(12) Patent Application Publication
(10) Pub. No.: US 2017/0165940 A1
(43) Pub. Date: Jun. 15, 2017

(54) LAMINATE AND METHOD OF PRODUCTION OF BUILT-UP BOARD

(71) Applicant: ZEON CORPORATION, Tokyo (JP)

(72) Inventor: Yuki Hayashi, Tokyo (JP)

(73) Assignee: ZEON CORPORATION, Tokyo (JP)

(21) Appl. No.: 15/116,930

(22) PCT Filed: Feb. 10, 2015
(86) PCT No.: PCT/JP2015/053609

§ 371 Date: Aug. 5, 2016

(30) Foreign Application Priority Data
Feb. 14, 2014 (JP) 2014-026175

(51) Int. Cl. B32B 5/02; B32B 5/00; B32B 5/22; H05K 1/05; G03F 7/038; B32B 5/26

(52) U.S. Cl. CPC B32B 5/02; B32B 5/00; B32B 5/22; H05K 1/056; G03F 7/038

(57) ABSTRACT

A laminate for forming a resin insulating layer of a built-up board, comprising a support film, and a resin film which is formed on the support film by using a resin composition containing a radical polymerizable compound, wherein the resin film is laminated, while maintained in a state where the resin film is laminated on the support film, on a base member constituting the built-up board in a state contacting the base member and is polymerized to thereby form a resin insulating layer of the built-up board is provided.

### TECHNICAL FIELD

The present invention relates to a laminate for forming a build-up layer of a built-up board and a method of production of a built-up board, more particularly a laminate suitable for production of a built-up board which has a resin insulating layer reduced in dielectric tangent and is suitably used for high frequency applications and a method of production of a built-up board using that laminate.

### BACKGROUND ART

In the past, as a method of production of a circuit board such as a multilayer printed circuit board, there has been known a method of laminating an electrical resin insulating layer comprised of a plurality of B-stage formed prepreg sheets obtained by impregnating glass cloth with an epoxy resin on an inside layer circuit board famed with circuits and pressing the same, then forming through holes to establish conduction between the layers. However, with this method, there were the problem that massive facilities and a long time were required for laminating and pressing, heating, and press-forming and therefore the cost became high and the problem that since glass cloth with a relatively high dielectric constant was used for the prepreg sheets, there was a limit to how thin the thickness between layers could be made and defects in the insulating ability are occurred by migration between through holes.

Therefore, as a method to solve this problem, a built-up type of multilayer circuit board produced by alternately stacking inside layer circuit boards and resin insulating layers obtained by curing a cured curable resin is being focused on (for example, see the above Patent Document 1).

On the other hand, in recent years, in the field of data transmission, demand for higher frequencies, higher densities, etc. has been rising, and higher precision, multilayered, finer resolution multilayer circuit boards are being developed. Such improvement of these properties is being sought in such built-up type multilayer circuit boards as well. In particular, in circuit boards used for data transmission in the high frequency region, materials with small transmission loss are being sought. As such a material with small transmission loss, for example, a cured resin obtained by polymerizing a radical polymerizable compound having a vinyl group is known.

However, a built-up type multilayer circuit board is obtained by laminating an inside layer circuit board and a curable resin and curing the curable resin to thereby form a multilayer structure, but due to the characteristics of the production process, the curing reaction of the curable resin is generally performed in an air environment. For this reason, when using a radical reactive compound such as a radical polymerizable compound having a vinyl group as the curable resin for forming the resin insulating layers of such a built-up type multilayer circuit board, the effect of the air causes the polymerization reaction to not proceed, so it is difficult to use this for applications of such a built-up type of multilayer circuit board.

### PRIOR ART DOCUMENTS

### Patent Documents

Patent Document 1: Japanese Patent Publication No. 2002-94234A

### SUMMARY OF INVENTION

### Problem to be Solved by the Invention

The present invention has as its object the provision of a laminate provided with a resin insulating layer reduced in dielectric tangent and suitable for production of a built-up board suitably used for high frequency applications and a method of production of a built-up board using that laminate.

### Means for Solving the Problems

The inventors engaged in intensive research for achieving the above object and as a result discovered that by using a laminate provided with a support film and a resin film which is famed on the support film by using a resin composition including a radical polymerizable compound and by laminating the resin film constituting the laminate, while the resin film is laminated on the support film, on a base member constituting the built-up board in a state contacting the base member and polymerizing the resin film to thereby form a resin insulating layer, it is possible to achieve the above object, and thereby completed the present invention.

That is, according to the present invention, there are provided
(1) A laminate for forming a resin insulating layer of a built-up board, comprising a support film, and a resin film which is formed on the support film by using a resin composition containing a radical polymerizable compound, wherein the resin film is laminated, while maintained in a state where the resin film is laminated on the support film, on a base member constituting the built-up board in a state contacting the base member and is polymerized to thereby form a resin insulating layer of the built-up board,
(2) the laminate according to (1), wherein the resin composition further contains a radical generator which is solid at ordinary temperature,
(3) the laminate according to (2), wherein the radical generator has a one-minute half life temperature of 100° C. or more,
(4) the laminate according to any one of (1) to (3), wherein the radical polymerizable compound is a polyfunctional radical polymerizable compound having two or more vinyl groups at a molecule end and/or side chain,
(5) the laminate according to any one of (1) to (4), wherein an oxygen transmission rate of the support film at 20° C. under a dry condition is 2500 (cc/m²/hr/atm) or less,
(6) the laminate according to any one of (1) to (5), wherein the support film has a mold release layer at its surface and the resin film is formed on a surface of the support film where the mold release layer is formed, and
(7) A method of production of a built-up board comprising:

preparing a laminate comprising a support film and a resin film which is formed on the support film by using a resin composition containing a radical polymerizable compound; and

laminating the laminate, while the resin film is maintained in a state where the resin film is laminated on the support film, on a base member constituting the built-up board in a state contacting the base member and polymerizing the resin film to thereby form a resin insulating layer.

### Effects of Invention

According to the present invention, a laminate provided with a resin insulating layer reduced in dielectric tangent and able to give a built-up board suitably used for high frequency applications and a method of production of a built-up board using that laminate can be provided.

### DESCRIPTION OF EMBODIMENTS

The laminate of the present invention is a laminate for forming a resin insulating layer of a built-up board, comprising a support film, and a resin film which is formed on the support film by using a resin composition containing a radical polymerizable compound, wherein the resin film is laminated, while maintained in a state where the resin film is laminated on the support film, on a base member constituting the built-up board in a state contacting the base member and is polymerized to thereby form a resin insulating layer of the built-up board.

(Resin Composition)

First, a resin composition used for obtaining the resin film constituting the laminate of the present invention will be explained.

The resin composition used in the present invention includes at least a radical polymerizable compound. The radical polymerizable compound is not particularly limited so long as a compound exhibiting radical polymerizability by the action of a radical generator etc., but for example a compound having a vinyl group at a molecule end and/or side chain may be mentioned. As such a compound having a vinyl group at a molecule end and/or side chain, for example, a monofunctional radical polymerizable compound having one vinyl group at the molecule end and/or side chain and a polyfunctional radical polymerizable compound having two or more vinyl groups at the molecule end and/or side chain may be mentioned.

As a monofunctional radical polymerizable compound, for example, a
(meth)acrylic acid ester such as methyl (meth)acrylate, ethyl (meth)acrylate,
n-propyl (meth)acrylate, i-propyl (meth)acrylate, n-butyl (meth)acrylate,
s-butyl (meth)acrylate, t-butyl (meth)acrylate, n-amyl (meth)acrylate,
s-amyl (meth)acrylate, t-amyl (meth)acrylate, n-hexyl (meth)acrylate,
2-ethylhexyl (meth)acrylate, isodecyl (meth)acrylate,
tridecyl (meth)acrylate, cyclohexyl (meth)acrylate,
cyclohexylmethyl (meth)acrylate, octyl (meth)acrylate, lauryl (meth)acrylate,
stearyl (meth)acrylate, benzyl (meth)acrylate, phenyl (meth)acrylate,
isobornyl (meth)acrylate, adamantyl (meth)acrylate,
tricyclodecanyl (meth)acrylate, 2-hydroxyethyl (meth)acrylate,
2-hydroxypropyl (meth)acrylate, 3-hydroxypropyl (meth)acrylate,
2-hydroxybutyl (meth)acrylate, 3-hydroxybutyl (meth)acrylate,
4-hydroxybutyl (meth)acrylate, 2-methoxyethyl (meth)acrylate,
2-ethoxyethyl (meth)acrylate, phenoxyethyl (meth)acrylate,
tetrahydrofurfuryl (meth)acrylate, glycidyl (meth)acrylate,
β-methylglycidyl (meth)acrylate, β-ethylglycidyl (meth)acrylate,
(3,4-epoxycyclohexyl(methyl (meth)acrylate,
N,N-dimethylaminoethyl (meth)acrylate, methyl α-hydroxymethylacrylate, and
ethyl α-hydroxymethylacrylate;

an unsaturated monocarboxylic acid such as (meth)acrylic acid, crotonic acid, cinnamic acid, and vinylbenzoic acid;
a conjugated diene such as 1,3-butadiene, isoprene, and chloroprene;
a vinyl ester such as vinyl acetate, vinyl propionate, vinyl butyrate, and vinyl benzoate;
a vinyl ether such as methylvinyl ether, ethylvinyl ether, propylvinyl ether, butylvinyl ether, 2-ethylhexylvinyl ether, n-nonylvinyl ether, laurylvinyl ether, cyolohexylvinyl ether, methoxyethylvinyl ether, ethoxyethylvinyl ether, methoxyethoxyethylvinyl ether, methoxypolyethyleneglycolvinyl ether, 2-hydroxyethylvinyl ether, and 4-hydroxybutylvinyl ether;
an N-vinyl compound such as N-vinyl pyrrolidone, N-vinyl caprolactam, N-vinyl imidazole, N-vinyl morpholine, and N-vinyl acetoamide;
an unsaturated isocyanate such as isocyanatoethyl (meth)acrylate and allyl isocyanate; etc. may be mentioned.

Further, as the polyfunctional radical polymerizable compound, for example, a polyfunctional (meth)acrylate such as ethyleneglycol di(meth)acrylate (ethyleneglycol diacrylate and/or ethyleneglycol dimethacrylate, same below), diethyleneglycol di(meth)acrylate, polyethyleneglycol di(meth)acrylate, propyleneglycol di(meth)acrylate, butyleneglycol di(meth)acrylate, hexanediol di(meth)acrylate, cyclohexane dimethanol di(meth)acrylate, bisphenol A alkyleneoxide di (meth)acrylate, bisphenol F alkyleneoxide di(meth)acrylate, trimethylolpropane tri(meth)acrylate, ditrimethylolpropane tetra(meth)acrylate, glycerin tri(math)acrylate, pentaerythritol tetra(meth)acrylate, dipentaerythritol penta(meth)acrylate, dipentaerythritol hexa(meth)acrylate, ethylene oxide-modified trimethylolpropane tri(meth)acrylate, ethylene oxide-modified ditrimethylolpropane tetra(meth)acrylate, ethylene oxide-modified pentaerythritol tetra(meth)acrylate, ethylene oxide-modified dipentaerythritol hexa(meth)acrylate, propylene oxide-modified trimethylolpropane tri(meth)acrylate, propylene oxide-modified ditrimethylolpropane tetra(meth)acrylate, propylene oxide-modified pentaerythritol tetra(meth)acrylate, propylene oxide-modified dipentaerythritol hexa(meth)acrylate, ε-caprolactone-modified trimethylolpropane tri(meth)acrylate, ε-caprolactone-modified ditrimethylolpropane tetra(math)acrylate, ε-caprolactone-modified pentaerythritol tetra(meth)acrylate, and ε-caprolactone-modified dipentaerythritol hexa(meth)acrylate;

a polyfunctional vinyl ether such as ethyleneglycol divinyl ether, diethyleneglycol divinyl ether, polyethyleneglycol divinyl ether, propyleneglycol divinyl ether, butyleneglycol divinyl ether, hexanediol divinyl ether, bisphenol A alkyleneoxide divinyl ether, bisphenol F alkyleneoxide divinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, ethylene oxide-modified trimethylolpropane trivinyl ether, ethylene oxide-modified ditrimethylolpropane tetravinyl ether, ethylene oxide-modified pentaerythritol tetravinyl ether, and ethylene oxide-modified dipentaerythritol hexavinyl ether;
a vinyl ether-group containing (meth)acrylic acid ester such as
2-vinyloxyethyl(meth)acrylate, 3-vinyloxypropyl(meth)acrylate,
1-methyl-2-vinyloxyethyl(meth)acrylate, 2-vinyloxypropyl(meth)acrylate,
4-vinyloxybutyl(meth)acrylate, 4-vinyloxycyclohexyl(meth)acrylate,
5-vinyloxypentyl(meth)acrylate, 6-vinyloxyhexyl(meth)acrylate,
4-vinyloxmethylcyclohexylmethyl (meth)acrylate,
p-vinyloxymethylphenylmethyl (meth)acrylate, 2-(vinyloxyethoxy)ethyl (meth)acrylate, and 2-(vinyloxyethoxyethoxyethoxy)ethyl(meth)acrylate;

a polyfunctional allyl ether such as ethyleneglycol diallyl ether, diethyleneglycol diallyl ether, polyethyleneglycol diallyl ether, propyleneglycol diallyl ether, butyleneglycol diallyl ether, hexanediol diallyl ether, bisphenol A alkylene oxide diallyl ether, bisphenol F alkylene oxide diallyl ether, trimethylolpropane triallyl ether, ditrimethylolpropane tetraallyl ether, glycerine triallyl ether, pentaerythritol tetraallyl ether, dipentaerythritol pentaallyl ether, dipentaerythritol hexaallyl ether, ethylene oxide-modified triflethylolpropane triallyl ether, ethylene oxide-modified ditrimethylolpropane tetraallyl ether, ethylene oxide-modified pentaerythritol tetraallyl ether, and ethylene oxide-modified dipentaerythritol hexaallyl ether;
an allyl group-containing (meth)acrylic acid ester such as allyl (meth)acrylate;
a polyfunctional (meth)acryloyl group-containing isocyanurate such as tri(acryloyloxyethyl)isocyanurate, tri(methacryloyloxyethyl)isocyanurate, alkylene oxide-modified tri(acryloyloxyethyl)isocyanurate, and alkylene oxide-modified tri(methacryloyloxyethyl)isocyanurate;
a polyfunctional allyl group-containing isocyanate such as triallyl isocyanurate and triallyl isocyanurate prepolymer;
a polyfunctional urethane (meth)acrylate obtained by reaction of a polyfunctional isocyanate such as tolylene diisocyanate, isophoron diisocyanate and xylylene diisocyanate, and a hydroxyl group-containing (meth)acrylic acid ester such as 2-hydroxyethyl (meth)acrylate and 2-hydroxypropyl (meth)acrylate;
a polyfunctional aromatic vinyl such as divinyl benzene;
a vinyl ester such as divinyl adipate;
a diallyl phthalate resin comprised of dially o-phthalate, diallyl isophthalate, and diallyl terephthalate alone or in two types or more copolymerized;
a vinyl benzyl-based compound represented by the following general formula (1) or (2); etc. may be mentioned.

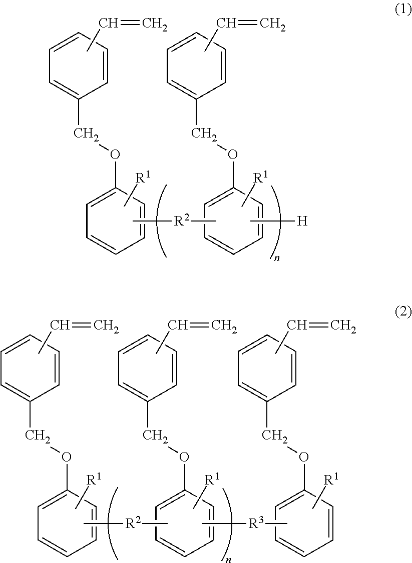

(in the above general formulas (1) and (2), R¹ is a hydrogen atom or hydrocarbon group having 1 to 10 carbon atoms, R² is a hydrocarbon group having 1 to 30 carbon atoms, R³ is a hydrocarbon group having 1 to 20 carbon atoms, and “n” is an integer of 1 to 20.)

Note that, the vinylbenzyl ether compound represented by the above general formula (1) or (2) can, for example, be obtained by reacting the corresponding phenol resin and vinylbenzyl halide in the presence of an alkali metal hydroxide.

The above-mentioned radical polymerizable compound may be used alone or as two types or more combined, but from the viewpoint of giving the resin film after the polymerization reaction one having a cross-linked structure, use of at least a polyfunctional radical polymerizable compound having two or more vinyl groups at the molecule end and/or side chain is preferable.

Further, the resin composition used in the present invention may further contain a radical generator. The radical generator is not particularly limited so long as a compound which generates radicals by heat or light and thereby causes the above-mentioned radical polymerizable compound to polymerize, but for example, aromatic ketones, onium salt compounds, organic peroxides, thio compounds, hexaaryl biimidazole compounds, ketoxime ester compounds, borate compounds, azimium compounds, metallocene compounds, active ester compounds, compounds having carbon-halogen bonds, azo-based compounds, bibenzyl compounds, etc. may be mentioned. Among these as well, organic peroxides and bibenzyl compounds are preferable, from the viewpoint of being able to lower the polymerization temperature of the resin film obtained by forming the resin composition, organic peroxides are preferable, or from the viewpoint of being able to make the dielectric tangent of the resin insulating layer obtained by polymerizing the resin film obtained by forming the resin composition better, bibenzyl compounds are preferable. These may be selected as desired.

As specific examples of the organic peroxide, dicumyl peroxide, cumen hydroxyl peroxide, t-butylcumyl peroxide, p-mentane peroxide, di-t-butyl peroxide, 1,3-bis(t-butylperoxyisopropyl)benzene,
1,4-bis(t-butylperoxyisopropyl)benzene,
1,1-di-t-butylperoxy-3,3-trimethyl cyclohexane, 4,4-bis-(t-butyl-peroxy)-n-butyl valerate, 2,5-dimethyl-2,5-t-butylperoxyhexane,
2,5-dimethyl-2,5-di-t-butylperoxyhexine-3,1,1-di-t-butylperoxy-3,5,5-trimethyl cyclohexane, p-chlorobenzoyl peroxide, t-butylperoxyisopropyl carbonate, t-butylperoxy benzoate, etc. may be mentioned.

As the bibenzyl compound, for example, a compound represented by the following general formula (3) may be mentioned.

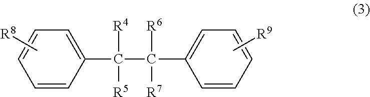

(in which general formula (3), R⁴, R⁵, R⁶, R⁷, R⁸, and R respectively independently are a hydrogen atom or hydrocarbon group having 1 to 20 carbon atoms.)

As specific examples of the compound represented by the the above general formula (3), 2,3-dimethyl-2,3-diphenylbutane, α,α′-dimethoxy-α,α′-diphenylbibenzyl, α,α′-diphenyl-α-methoxybibenzyl, α,α′-dimethoxy-α,α′-dimethylbibenzyl, α,α′-dimethoxybibenzyl, 3,4-dimethyl-3,4-diphenyl-n-hexane 2,2,3,3-tetraphenylsuccinonitrile dibenzyl, etc. may be mentioned.

Note that, in the present invention, as the radical polymer table compound, a compound other than a compound having a vinyl group at a molecule end and/or side chain, for example, bismaleimide or a Michael adduct of bismaleimide etc. may be used together with the above compound having a vinyl group at a molecule end and/or side chain.

Further, in the present invention, when polymerizing the resin film obtained by using the resin composition, from the viewpoint of being able to suppress foaming in the resin film after the polymerization reaction (resin insulating layer), a radical generator which is solid at ordinary temperature (for example, 25° C.) is preferably used. In particular, if foams end up forming in the resin film after the polymerization reaction, the obtained built-up board sometimes ends up falling in electrical properties, so to prevent formation of such foams, in the present invention, it is preferable to use a radical generator which is solid at ordinary temperature.

The radical generator used in the present invention is not particularly limited in one-minute half life temperature, but 100° C. or more is preferable, while 150° C. or more is more preferable. Note that, the upper limit of the one-minute half life temperature of the radical generator is not particularly limited, but is usually 300° C. or less. By making the one-minute half life temperature of the radical generator the above range, when adding a solvent into the resin composition and forming the resin film by the coating method etc., the polymerization reaction will not proceed even if making the drying temperature of the solvent a relatively high temperature, so due to this, the productivity can be improved.

In the resin composition used in the present invention, the content of the radical generator is preferably 0.01 to 10 parts by weight with respect to 100 parts by weight of the radical polymerizable compound, more preferably 0.1 to 10 parts by weight, still more preferably 0.5 to 5 parts by weight. By making the content of the radical generator the above range, the laminate obtained by polymerizing the resin film famed using the resin composition can be made one having a sufficient cross-linking density and having the desired physical properties, so this is preferable.

Further, the resin composition used in the present invention may also contain a solvent in addition to the above-mentioned radical polymerizable compound and radical generator. The solvent is not particularly limited, but one known as a solvent of a resin composition, for example, a linear ketone such as acetone, methylethylketone, cyclopentanone, 2-hexanone, 3-hexanone, 2-heptanone, 3-heptanone, 4-heptanone, 2-octanone, 3-octanone, and 4-octanone; an alcohol such as n-propyl alcohol, isopropyl alcohol, n-butyl alcohol, and cyclohexanol; an ether such as ethyleneglycol dimethyl ether, ethyleneglycol diethyl ether, and dioxane; an alcohol ether such as ethyleneglycol monomethyl ether and ethyleneglycol monoethyl ether; an ester such as propyl formate, butyl formate, propyl acetate, butyl acetate, methyl propionate, ethyl propionate, methyl butyrate, ethyl butyrate, methyl lactate, and ethyl lactate; a cellosolve ester such as cellosolve acetate, methyl cellosolve acetate, ethyl cellosolve acetate, propyl cellosolve acetate, and butyl cellosolve acetate; a propyleneglycol such as propyleneglycol, propyleneglycol monomethyl ether, propyleneglycol monomethyl ether acetate, propyleneglycol monoethyl ether acetate, and propyleneglycol monobutyl ether; a diethyleneglycol such as diethyleneglycol monomethyl ether, diethyleneglycol monoethyl ether, diethyleneglycol dimethyl ether, diethyleneglycol diethyl ether, and diethyleneglycol methylethyl ether; a saturated γ-lactone such as γ-butyrolactone, γ-valerolactone, γ-caprolactone, and γ-caprylolactone; a halogenated hydrocarbon such as trichloroethylene; an aromatic hydrocarbon such as toluene and xylene; and a polar solvent such as dimethylacetoamide, dimethylformamide, and N-methylacetoamide; etc. may be mentioned. These solvents may be used alone or as two types or more combined. Note that, when including a solvent in the resin composition, the solvent is usually removed after forming the resin film.

Also, the resin composition used in the present invention may further contain various types of add tines such as a filler, flame retardant, coloring agent, antioxidant, and photostabilizer.

As the filler, glass powder, ceramic powder, silica, etc. may be mentioned. Two types or more of these fillers may be jointly used. As the fillers, ones treated on the surface by a silane coupling agent etc. may also be used. The content of the filler is preferably 50 to 500 parts by weight with respect to 100 parts by weight of the radical polymerizable compound, more preferably 50 to 400 parts by weight.

As the flame retardant, a known halogen-based flame retardant or nonhalogen-based flame retardant may be used. As a halogen-based flame retardant, tris(2-chloroethyl)phosphate, tris(chloropropyl)phosphate, tris(dichloropropyl)phosphate, chlorinated polystyrene, chlorinated polyethylene, high chlorinated polypropylene, chlorosulfonated polyethylene, hexabromobenzene, decabromodiphenyl oxide, bis(tribromophenoxy)ethane,
1,2-bis(pentabromophenyl)ethane, tetrabromobisphenol S, tetradecabromodiphenoxybenzene,
(4-hydroxy-3,5-dibromophenylpropane), pentabromotoluene, etc. may be mentioned.

As the coloring agent, a dye, pigment, etc. may be mentioned. There are various types of dyes. One may be suitably selected and use from among the known dyes.

(Laminate)

Next, the laminate of the present invention will be explained. The laminate of the present invention is obtained by forming a resin film on a support film using the above resin composition. The resin film provided at the laminate of the present invention is a resin film for forming a resin insulating layer of the built-up board. The laminate is laminated, while maintained in a state where the resin film is laminated on the support film, on a base member (for example, core board etc.) constituting the built-up board in a state contacting the base member and is polymerized to thereby form a resin insulating layer of the built-up board.

In particular, according to the laminate of the present invention, since a polymerization reaction is performed, while the resin film is maintained in a state where the resin film is laminated on the support film, in a state contacting the base member forming the built-up board, due to this, it is possible to prevent the polymerization reaction of the resin film, specifically, the polymerization reaction of the radical polymerizable compound contained in the resin film, from ending up being obstructed due to the effect of the air. Due to this, the polymerization reaction can be made to proceed well even in the case of performing the polymerization reaction in an air atmosphere. For this reason, the laminate of the present invention can be suitably used for applications in which performing a polymerization reaction in an air atmosphere is sought, specifically, an application of a built-up type of multilayer circuit board.

The support film is not particularly limited, but from the viewpoint of being able to more suitably prevent air from ending up passing through the support film and thereby the polymerization reaction of the radical polymerizable compound contained in the resin film from ending up being obstructed when the resin film is laminated, while maintained in a state where the resin film is laminated on the support film, on a base member constituting the built-up board in a state contacting the base member and is polymerized, and as a result the polymerization reaction of the radical polymerizable compound contained in the resin film can proceed well, a resin film with an oxygen transmission rate at 20° C. under dry conditions of 5000 (cc/m²/hr/atm) or less is preferable, while a resin film with 2500 (cc/m²/hr/atm) or less is particularly preferable.

As such a resin film, for example, a cyclic polyolefin-based resin, polystyrene-based resin, acrylonitrile-styrene copolymer (AS resin), acrylonitrile-butadiene-styrene copolymer (ABS resin), poly(meth)acrylic-based resin, polycarbonate-based resin, a polyester-based resin such as polyethylene terephthalate, and polyethylene naphthalate, polyamide-based resin such as various nylons, a polyimide resin, polyurethane-based resin, fluororesin, acetal-based resin, cellulose-based resin, polyether sulfone-based resin, etc. may be mentioned. Among these as well, from the viewpoint of the low oxygen transmission rate and the ability to make the polymerization reaction of the radical polymerizable compound contained in the resin film proceed particularly well, a polyester-based resin such as polyethylene terephthalate and polyethylene naphthalate and a polyimide resin are preferable, polyethylene terephthalate and polyethylene naphthalate are more preferable, and polyethylene terephthalate is particularly preferable.

Note that, the support film used in the present invention used may be one which is treated on its surface for mold release so as to improve the peelability when making the polymerization reaction of the radical polymerizable compound contained in the resin film proceed and due to this forming the resin insulating layer after the polymerization reaction on the base member, then peeling off the support film from the formed resin insulating layer. As the treatment for mold release, the method of forming a mold release layer comprised of a silicone-based resin etc. on the surface may be mentioned. For example, when using a support film with a good mold release property such as a polyimide etc., sufficient peelability can be exhibited even without such mold release treatment, but even when using a support film not necessarily sufficient in peelability such as one made of polyethylene terephthalate and polyethylene naphthalate, performing such mold release treatment enables sufficient peelability to be imparted.

The thickness of the support film used in the present invention is not particularly limited, but from the viewpoint of improving the handling ability of the laminate, is preferably 150 μm or less, more preferably 100 μm or less. The lower limit of thickness of the support film is usually 10 μm or more.

The method of forming the resin film on such a support film using the above-mentioned resin composition is not particularly limited, but usually the coating method is used.

The coating method is, for example, the method of coating the resin composition, then heating it to dry to remove the solvent. As the method of coating the resin composition, for example, various methods such as the spray method, spin coat method, roll coat method, die coat method, doctor blade method, rotary coat method, bar coat method, and screen printing method may be employed. The heating and drying conditions differ depending on the types and ratios of the ingredients, but are usually 20 to 300° C., preferably 30 to 200° C., for usually 0.5 to 90 minutes, preferably 1 to 60 minutes, more preferably 1 to 30 minutes.

The thickness of the resin film is not particularly limited and may be suitably set in accordance with the application, but is preferably 0.1 to 100 μm, more preferably 0.5 to 50 μm, still more preferably 0.5 to 30 μm.

(Method of Production of Built-up Board)

Next, the method of production of a built-up board of the present invention will be explained. The method of production of a built-up board of the present invention has a step of laminating the above-mentioned laminate of the present invention, while the resin film is maintained in a state where the resin film is laminated on the support film, on a base member constituting the built-up board in a state contacting the base member and polymerizing the resin film to thereby form a resin insulating layer.

The base member is not particularly limited, but for example a core board and also a board comprised of a core board on which conductor circuits and resin insulating layers formed using the laminate of the present invention are alternately laminated etc. may be mentioned. Alternatively, laminates of the present invention may be laminated so that the resin films contact each other so that one acts as the base member for the other.

The polymerization conditions when laminating the laminate, while the resin film is maintained in a state where the resin film is laminated on the support film, on the base member in the state contacting the base member and polymerizing the resin film are not particularly limited. The polymerization conditions may be suitably selected in accordance with the type etc. of the radical polymerizable compound or radical generator contained in the resin film, but the polymerization temperature is usually 30 to 300° C., preferably 50 to 250° C., while the polymerization time is usually 0.1 to 5 hours, preferably 0.5 to 3 hours. Further, the laminate of the present invention, as explained above, is one which is polymerized by bringing it into contact, while the resin film is maintained in a state where the resin film is laminated on the support film, with the base member forming the built-up board, so it is possible to prevent the polymerization reaction of the radical polymerizable compound contained in the resin film from ending up being obstructed due to the effect of the air. Therefore the above polymerization reaction can be performed in an air atmosphere.

Next, the radical polymerizable compound contained in the resin film is polymerized to thereby form a resin insulating layer (polymerized resin film) on the base member, then peeling off the support film from the resin insulating layer after polymerization. The method of peeling off the support film is not particularly limited, but a known method may be employed.

Further, by repeatedly performing the step of forming conductor circuits by predetermined patterns on the thus formed resin insulating layer and furthermore forming a resin insulating layer on this using the laminate of the present invention, it is possible to obtain a built-up type of multilayer circuit board.

The method of forming the conductor circuits is not particularly limited, but from the viewpoint of being able to form conductor circuits excellent in adhesion to the resin insulating layer, forming them by electroless plating is preferable.

For example, when using electroless plating to form conductor circuits, first, before forming a metal thin film on the surface of the resin insulating layer, the general practice is to deposit catalyst nuclei such as silver, palladium, zinc, and cobalt on the resin insulating layer. The method of depositing the catalyst nuclei on an electrical insulating layer is not particularly limited. For example, the method of dipping the resin insulating layer in a solution of a metal compound of silver, palladium, zinc, cobalt, etc. or their salts or complexes dissolved in water or an organic solvent such as alcohol or chloroform in a concentration of 0.001 to 10 wt % (in accordance with need, an acid, alkali, complexing agent, reducing agent, etc. may also be included), then reducing the metal etc. may be mentioned.

As the electroless plating solution used for the electroless plating method, a known self-catalyzing type electroless plating solution may be used. The type of metal, type of reducing agent, type of complexing agent, concentration of hydrogen ions, concentration of dissolved oxygen, etc. in the plating solution are not particularly limited. For example, an electroless plating solution such as an electroless copper plating solution using ammonium hypophosphite, hypophosphorus acid, ammonium borohydride, hydrazine, formalin, etc. as a reducing agent; an electroless nickel-phosphorus plating solution using sodium hypophosphite as a reducing agent; an electroless nickel-boron plating solution using dimethylamine borane as a reducing agent; an electroless palladium plating solution; an electroless palladium-phosphorus plating solution using sodium hypophosphite as a reducing agent; an electroless gold plating solution; an electroless silver plating solution; and an electroless nickel-cobalt-phosphorus plating solution using sodium hypophosphite as a reducing agent can be used.

After forming the metal thin film, to improve the adhesion etc., it is also possible to heat the metal thin film. The heating temperature is usually 50 to 350° C., preferably 80 to 250° C. Note that, at this time, the heating may be performed under pressed conditions. As the pressing method at this time, for example, the method of using a physical pressing means such as a hot press machine and press heating rolls may be mentioned. The pressure applied is usually 0.1 to 20 MPa, preferably 0.5 to 10 MPa. In this range, high adhesion of the metal thin film and resin insulating layer can be secured.

Further, it is possible to for n resist patterns for plating on the metal thin film fouled in this way and further electroplate or otherwise wet plate this to grow the plating (plating up), then remove the resist and further etch the metal thin film to pattern it and thereby form predetermined patterns of electrical circuits.

The built-up board obtained by the above such method of production of the present invention is obtained using the laminate of the present invention and is provided with a resin insulating layer reduced in dielectric tangent, so, for example, can be suitably used for various types of electronic apparatuses such as a mobile phone, PHS, smartphone, notebook PC, PDA (personal digital assistant), portable television phone, PC, supercomputer, server, router, liquid crystal projector, engineering workstation (EWS), pager, word processor, television, viewfinder type or monitor direct viewing type video tape recorder, electronic memo book, electronic desktop calculator, car navigation system, POS terminal, or device provided with a touch panel.

### EXAMPLES

Below, examples and comparative examples will be given to explain the present invention more specifically. In the examples, “parts”, unless otherwise indicated, are based on weight.
Note that, the definitions and methods of evaluation of the different properties are as follows.

<Presence of Obstruction to Polymerization>

The resin film after the polymerization reaction was dipped in toluene at ordinary temperature. Whether the resin film after the polymerization reaction dissolved in the toluene was observed to evaluate the presence of obstruction to polymerization.

<Dielectric Tangent>

The resin film after the polymerization reaction was measured for dielectric tangent at 10 GHz using a cavity perturbation method dielectric constant measuring apparatus and was evaluated by the following criteria.
Good: Dielectric tangent of less than 0.005
Poor: Dielectric tangent of 0.005 or more

### EXAMPLE 1

### Preparation of Resin Composition

In accordance with the method disclosed in Japanese Patent Publication No. 2007-119531A, in the presence of a quaternary ammonium salt (tetra-n-butylammonium bromide), a phenol resin (product name “SK Resin HE-100C-30”, made by Air Water Inc.) and vinylbenzyl chloride (product name “CMS-P”, made by AGC Seimi Chemical, m/p isomers: 50/50 wt % mixture) were made to react in a water/organic solvent mixture using an alkali metal hydroxide (sodium hydroxide) as a dehydrohalogenation agent at 80° C. to obtain a vinylbenzyl etherified phenol resin.

Further, to 100 parts of a radical polymerizable compound comprised of the above obtained vinylbenzyl etherified phenol resin, 1.5 parts of a radical generator comprised of dicumyl peroxide (product name “Perkadox BC-FF”, made by Kayaku Akzo Corporation, solid at ordinary temperature), and 100 parts of a filler comprised of surface treated spherical silica obtained by treating spherical silica (product name “SO-C2”, made by Admatechs) using a methacrylic silane coupling agent and a solvent comprised of toluene were mixed to give a solid content concentration of 50% to thereby obtain a resin composition.

(Production of Laminate)

Further, the above obtained resin composition was coated on a support film comprised of a mold release PET film (product name “TR-6”, made by Toray, oxygen transmission rate at 20° C. under dry condition: 100 (cc/m²/hr/atm) or less) at the surface where the mold release layer was formed, by a die coater, then was heated under conditions of 80° C., 10 minutes to remove the solvent and thereby obtain a laminate comprised of a mold release PET formed with a thickness 50 μm resin film at the surface where the mold release layer was formed.

(Polymerization of Resin Film)

Using a thickness 0.8 mm, 150 mm square (vertical 150 mm, horizontal 150 mm) double sided copper clad board comprised of a core member obtained by impregnating a varnish containing a glass filler and halogen-free epoxy compound in glass fiber and thickness 18 μm copper foils provided on its two surfaces, one surface of the double sided copper clad board was microetched by contact of the copper foil surface with an organic acid to form a conductor layer with lines of a width and pitch of 50 μm and thickness of 18 μm to obtain an inner layer board.

Further, the obtained laminate was laminated, as is in the state where the resin film is laminated on the mold release PET film, on the above obtained inner layer at the surface where the conductor layer is formed so that the resin film contacts the inner layer board, then this was heated in an air atmosphere under conditions of 180° C., 1 hour to thereby polymerize the resin film. Further, the mold release PET film was peeled off from the resin film after the polymerization reaction. The thus obtained resin film after the polymerization reaction was measured and evaluated for the presence of obstruction to polymerization and dielectric tangent in accordance with the above methods. The results are shown in Table 1.

### EXAMPLE 2

When producing the laminate, except for using, instead of the mold release PET film (product name “TR-6”, made by Toray), the mold release PET film (product name “HN15”, made by Teijin Dupont Film, oxygen transmission rate at 20° C. under dry condition: 100 (cc/m²/hr/atm) or less), the same procedure was followed as in Example 1 to obtain a laminate. Except for changing the conditions at the time of the polymerization reaction to 200° C. for 1 hour, the same procedure was followed as in Example 1 to polymerize the resin film and the same procedure was followed to evaluate it. The results are shown in Table 1.

### EXAMPLE 3

When producing the laminate, except for using, instead of the mold release PET film (product name “TR-6”, made by Toray), a polyimide film (product name “Kapton 100V”, made by Toray, oxygen transmission rate at 20° C. under dry condition: 800 (cc/m²/hr/atm) or less), the same procedure was followed as in Example 1 to obtain a laminate. Except for changing the conditions at the time of the polymerization reaction to 200° C. for 1 hour, the same procedure was followed as in Example 1 to polymerize the resin film and the same procedure was followed to evaluate it. The results are shown in Table 1.

### EXAMPLE 4

Except for changing the conditions at the time of the polymerization reaction of the resin film to 200° C. for 2 hours, the same procedure was followed as in Example 1 to polymerize the resin film and the same procedure was followed to evaluate it. The results are shown in Table 1.

### EXAMPLE 5

### Preparation of Resin Composition

In accordance with the method disclosed in Japanese Patent Publication No. 2007-119531A, in the presence of a quaternary ammonium salt (tetra-n-butylammonium bromide), a phenol resin (product name “MEH7581SS”, made by Meiwa Chemical) and vinylbenzyl chloride (product name “CMS-P”, made by AGC Seimi Chemical, m/p isomers: 50/50 wt % mixture) were made to react in a water/organic solvent mixture using an alkali metal hydroxide (sodium hydroxide) as a dehydrohalogenation agent at 80° C. to obtain a vinylbenzyl etherified phenyl type phenol novolac resin.

Further, when preparing the resin composition, except for using, as the radical polymerizable compound, instead of 100 parts of vinylbenzyl etherified phenol resin, 100 parts of the above obtained vinylbenzyl etherified phenyl type phenol novolac resin and except for using, as the radical generator, instead of 1.5 parts of dicumyl peroxide, 1 part of 1,3-bis(t-butylperoxyisopropyl)benzene (product name “Perkadox 14SFL”, made by Kayaku Akzo Corporation, solid at ordinary temperature), the same procedure was followed as in Example 1 to obtain a resin composition. Further, using the obtained resin composition, the same procedure was followed as in Example 1 to obtain a laminate. Except for changing the conditions at the time of the polymerization reaction to 200° C. for 1 hour, the same procedure was followed as in Example 1 to polymerize the resin film and the same procedure was followed to evaluate it. The results are shown in Table 1.

### EXAMPLES 6 to 10

When preparing the resin composition, except for using, as the radical polymerizable compound, instead of 100 parts of vinylbenzyl etherified phenol resin, the compounds shown in Table 1 in the amounts shown in Table 1, the same procedure was followed as in Example 1 to obtain resin compositions. Further, using the obtained resin compositions, the same procedure was followed as in Example 1 to obtain laminates. Except for changing the conditions at the time of the polymerization reaction to 200° C. for 1 hour, the same procedure was followed as in Example 1 to polymerize the resin films and the same procedure was followed to evaluate them. The results are shown in Table 1.

Note that, details of the compounds shown in Table 1 are as follows.

Vinylbenzyl etherified cyclopentadiene-based phenol resin (produced by later explained method)

Diallyl phthalate prepolymer (product name “Daiso DAP A Prepolymer”, made by Daiso)

Triallyl isocyanurate prepolymer (product name “TALC Prepolymer”, made by Nippon Kasei)

2,2′-bis-[4-(4-maleimidephenoxy)phenyl]propane (product name “BMI-70”, made by K-I Chemical)

(2,5-dimethacryloyloxyphenyl)diphenylphosphine oxide (product name “W-2o”, made by Katayama Chemical)

Note that, the above-mentioned vinylbenzyl etherified dicyclopentadiene-based phenol resin was obtained by the following procedure. That is, in the presence of a quaternary ammonium salt (tetra-n-butylammonium bromide), a dicyclopentadiene-based phenol resin (product name “DPR#5000”, made by Mitsui Chemical) and vinylbenzyl chloride (product name “CMS-P”, made by AGC Seimi Chemical, m/p isomers: 50/50 wt % mixture) were made to react in a water/organic solvent mixture using an alkali metal hydroxide (sodium hydroxide) as a dehydrohalogenation agent at 80° C. to obtain a vinylbenzyl etherified dicyclopentadiene-based phenol resin.

### EXAMPLE 11

When preparing the resin composition, except for using, as a radical generator, instead of 1.5 parts of dicumyl peroxide, 1.5 parts of di-t-butyl peroxide (product name “Kayabutyl D”, made by Kayaku Akzo Corporation, liquid at ordinary temperature), the same procedure was followed as in Example 1 to obtain a resin composition. Further, using the obtained resin composition, instead of using a mold release PET film (product name “TR-6”, made by Toray), using a PET film not treated for mold release (product name “Lumirror T60”, made by Toray, oxygen transmission rate at 20° C. under dry conditions: 100 (cc/m²/hr/atm) or less), the same procedure was followed as in Example 1 to obtain a laminate, then the same procedure was followed to polymerize the resin film and the same procedure was followed to evaluate it. The results are shown in Table 2.

### EXAMPLE 12

When preparing the resin composition, except for using, as the radical generator, instead of 1.5 parts of dicumyl peroxide, 1.5 parts of methyl-2,5-di (t-butylperoxy) hexane (product name “Kayahexa AD”, made by Kayaku Akzo Corporation, liquid at ordinary temperature), the same procedure was followed as in Example 1 to obtain a resin composition. Further, using the obtained resin composition, the same procedure was followed as in Example 1 to obtain a laminate. Except for changing the conditions at the time of the polymerization reaction to 200° C. for 1 hour, the same procedure was followed as in Example 1 to polymerize the resin film and the same procedure was followed to evaluate it. The results are shown in Table 2.

### EXAMPLE 13

When producing the laminate, except for using, instead of the mold release PET film (product name “TR-6”, made by Toray), a PET film not treated for mold release (one same as in Example 12), the same procedure was followed as in Example 1 to obtain a laminate. Except for changing the conditions at the time of the polymerization reaction to 200° C. for 2 hours, the same procedure was followed as in Example 1 to polymerize the resin film and the same procedure was followed to evaluate them. The results are shown in Table 2.

### EXAMPLE 14

When preparing the resin composition, except for using, as the radical polymerizable compound, instead of 100 parts of the vinylbenzyl etherified phenol resin, 100 parts of an end methacrylate-modified polyphenylene ether oligomer (product name “SA9000”, made by SABIC) and for using, as the radical generator, 1.5 parts of instead of dicumyl peroxide, 1.5 parts of di-t-butylperoxide (one same as in Example 11), the same procedure was followed as in Example 1 to obtain a resin composition. Further, using the obtained resin composition, except for using, instead of a mold release PET film (product name “TR-6”, made by Toray), a polyimide film (one same as in Example 3), the same procedure was followed as in Example 1 to obtain a laminate and, except for changing the conditions at the time of the polymerization reaction to 200° C. for 1 hour, the same procedure was followed as in Example 1 to polymerize the resin film and the same procedure was followed to evaluate it. The results are shown in Table 2.

### COMPARATIVE EXAMPLE 1

When preparing the resin composition, except for using, as the radical polymerizable compound, instead of 100 parts of the vinylbenzyl etherified phenol resin, 50 parts of a dicyclopentadiene type polyfunctional epoxy resin (product name “EPICLON HP-7200”, made by DIC) and 50 parts of a dicyclopentadiene type novolac resin (GDP-6140, made by Gun-Ei Chemical Industry) and using, instead of 1.5 parts of the radical generator comprised of dicumyl peroxide, 1 part of epoxy curing agent comprised of 1-benzyl-2-phenylimidazole (product name “Curezol 1B2PZ”, made by Shikoku Chemicals), the same procedure was followed as in Example 1 to obtain a resin composition. Further, using the obtained resin composition, the same procedure was followed as in Example 1 to obtain a laminate, then the same procedure was followed to polymerize the resin film and the same procedure was followed to evaluate it. The results are shown in Table 2.

### COMPARATIVE EXAMPLE 2

When preparing a resin composition, except for using, instead of 50 parts of a dicyclopentadiene type novolac resin, 50 parts of an active ester resin (product name “EPICLON HPC-8000-65T”, made by DIC), the same procedure was followed as in Comparative Example 1 to obtain a resin composition. Further, using the obtained resin composition, the same procedure was followed as in Comparative Example 1 to obtain a laminate, then the same procedure was followed to polymerize the resin film and the same procedure was followed to evaluate it. The results are shown in Table 2.

### COMPARATIVE EXAMPLE 3

When producing a laminate, except for using, instead of the mold release PET film (product name “TR-6”, made by Toray), a PET film not treated for mold release (one same as in Example 11), the same procedure was followed as in Comparative Example 1 to obtain a laminate and except for peeling off the PET film from the resin film before the polymerization reaction of the resin film, then polymerizing the resin film, the same procedure was followed as in Comparative Example 1 to polymerize the resin film and the same procedure was followed to evaluate it. The results are shown in Table 2.

Table 1

TABLE 1

| | | | Examples | | | | | | | | | |
|---|---|---|---|---|---|---|---|---|---|---|---|---|
| | | | 1 | 2 | 3 | 4 | 5 | 6 | 7 | 8 | 9 | 10 |
| Radical | Vinylbenzyl etherified phenol | (parts) | 100 | 100 | 100 | 100 | | | | | 90 | |
| polymer- | resin | | | | | | | | | | | |
| izable | Vinylbenzyl etherified biphenyl | (parts) | | | | | 100 | | | 80 | | |
| compound | type phenol novolac resin | | | | | | | | | | | |
| | Vinylbenzyl etherified | (parts) | | | | | | | | | | 50 |
| | cyclopentadiene-based phenol resin | | | | | | | | | | | |
| | End eethacrylate-modified | (parts) | | | | | | | | | | |
| | polyphenylene ether oligomer | | | | | | | | | | | |
| | Diallyl phthalate prepolymer | (parts) | | | | | | 100 | 60 | | | 40 |
| | Triallyl isocyanurate prepolymer | (parts) | | | | | | | 20 | | | |
| | 2,2′-bis-[4-(4-maleimide- | (parts) | | | | | | | | 20 | | |
| | phenoxy)phenyl]propane | | | | | | | | | | | |
| | (2,5-dimethacryloyloxy- | (parts) | | | | | | | 5 | | 5 | 5 |
| | phenyl)diphenyl phosphine oxide | | | | | | | | | | | |
| | Triallyl isocyanurate | (parts) | | | | | | | 10 | | 5 | 5 |
| | Divinyl adipate | (parts) | | | | | | | 5 | | | |
| Epoxy | Dicyclopentadiene type poly- | (parts) | | | | | | | | | | |
| compound | functional epoxy resin | | | | | | | | | | | |
| | Dicyclopentadiene type novolac | (parts) | | | | | | | | | | |
| | resin | | | | | | | | | | | |
| | Active ester resin | (parts) | | | | | | | | | | |
| Radical | Dicumyl peroxide | (parts) | 1.5 | 1.5 | 1.5 | 1.5 | | 1.5 | 1.5 | 1.5 | 1.5 | 1.5 |
| initiator | 1,3-bis(t-butylperoxy- | (parts) | | | | | 1 | | | | | |
| | isopropyl)benzene | | | | | | | | | | | |
| | Di-t-butylperoxide | (parts) | | | | | | | | | | |
| | 2,5-dimethyl-2,5-di(t- | (parts) | | | | | | | | | | |
| | butylperoxy)hexane | | | | | | | | | | | |
| Epoxy | 1-benzyl-2-phenylimidazole | (parts) | | | | | | | | | | |
| curing | | | | | | | | | | | | |
| agent | | | | | | | | | | | | |
| Filler | Surface-treated spherical silica | (parts) | 100 | 100 | 100 | 100 | 100 | 100 | 100 | 100 | 100 | 100 |
| Support | Type of support film used | | Mold | Mold | Poly- | Mold | Mold | Mold | Mold | Mold | Mold | Mold |
| film | | | release | release | imide | release | release | release | release | release | release | release |
| | | | PET | PET | | PET | PET | PET | PET | PET | PET | PET |
| | | | (TR-6) | (HN15) | | (TR-6) | (TR-6) | (TR-6) | (TR-6) | (TR-6) | (TR-6) | (TR-6) |
| Polymer- | Polymerization temperature | (° C.) | 180 | 200 | 200 | 200 | 200 | 200 | 200 | 200 | 200 | 200 |
| ization | Polymerization time | (hour) | 1 | 1 | 1 | 2 | 1 | 1 | 1 | 1 | 1 | 1 |
| conditions | | | | | | | | | | | | |
| Results of | Presence of obstruction to | | None | None | None | None | None | None | None | None | None | None |
| evaluation | polymerization | | | | | | | | | | | |
| | Dielectric tangent | | Good | Good | Good | Good | Good | Good | Good | Good | Good | Good |

TABLE 2
Table 2

| | | | Examples | | | | Comparative Examples | | |
|---|---|---|---|---|---|---|---|---|---|
| | | | 11 | 12 | 13 | 14 | 1 | 2 | 3 |
| Radical | Vinylbenzyl etherified phenol resin | (parts) | 100 | 100 | 100 | | | | |
| polymer- | Vinylbenzyl etherified biphenyl type phenol novolac resin | (parts) | | | | | | | |
| izable | Vinylbenzyl etherified cyclopentadiene-based phenol resin | (parts) | | | | | | | |
| compound | End eethacrylate-modified polyphenylene ether oligomer | (parts) | | | | 100 | | | |
| | Diallyl phthalate prepolymer | (parts) | | | | | | | |
| | Triallyl isocyanurate prepolymer | (parts) | | | | | | | |
| | 2,2′-bis-[4-(4-maleimidephenoxy)phenyl]propane | (parts) | | | | | | | |
| | (2,5-dimethacryloyloxyphenyl)diphenyl phosphine oxide | (parts) | | | | | | | |
| | Triallyl isocyanurate | (parts) | | | | | | | |
| | Divinyl adipate | (parts) | | | | | | | |
| Epoxy | Dicyclopentadiene type polyfunctional epoxy resin | (parts) | | | | | 50 | 50 | 50 |
| compound | Dicyclopentadiene type novolac resin | (parts) | | | | | 50 | | 50 |
| | Active ester resin | (parts) | | | | | | 50 | |
| Radical | Dicumyl peroxide | (parts) | | | 1.5 | | | | |
| initiator | 1,3-bis(t-butylperoxyisopropyl)benzene | (parts) | | | | | | | |
| | Di-t-butylperoxide | (parts) | 1.5 | | | 1.5 | | | |
| | 2,5-dimethyl-2,5-di(t-butylperoxy)hexane | (parts) | | 1.5 | | | | | |
| Epoxy | 1-benzyl-2-phenylimidazole | (parts) | | | | | 1 | 1 | 1 |
| curing | | | | | | | | | |
| agent | | | | | | | | | |
| Filler | Surface-treated spherical silica | (parts) | 100 | 100 | 100 | 100 | 100 | 100 | 100 |
| Support | Type of support film used | | Non- | Mold | Non- | Poly- | Mold | Mold | Non-treated |
| film | | | treated | release | treated | imide | release | release | PET (Peeled |
| | | | PET | PET | PET | | PET | PET | off before |
| | | | | (TR-6) | | | (TR-6) | (TR-6) | polymer- |
| | | | | | | | | | ization) |
| Polymer- | Polymerization temperature | (° C.) | 180 | 200 | 200 | 200 | 180 | 180 | 180 |
| ization | Polymerization time | (hour) | 1 | 1 | 2 | 1 | 1 | 1 | 1 |
| conditions | | | | | | | | | |
| Results of | Presence of obstruction to polymerization | | None | None | None | None | None | None | None |
| evaluation | Dielectric tangent | | Good | Good | Good | Good | Poor | Poor | Poor |

As shown in Table 1 and Table 2, by causing a polymerization reaction of a resin film obtained by using a resin composition containing a radical polymerizable in a state where the resin film constituting a laminate is laminated on a support film and contacts a base member constituting an inside layer board, the obstruction to polymerization due to the air did not occurred and, further, the obtained resin film after the polymerization reaction was kept low in dielectric tangent and was suitable for high frequency applications (Examples 1 to 14).

On the other hand, when using, instead of a radical polymerizable compound, an epoxy compound to for n a resin film, regardless of the presence or absence of a support film at the time of polymerization (see Comparative Example 3), the obstruction to polymerization due to the air did not occurred, but the resin film after the polymerization reaction became high in dielectric tangent (Comparative Examples 1 to 3).

Note that, in Examples 1 to 10 and 13 where a radical generator which is a solid at ordinary temperature was used, no foams could be observed in the resin film after the polymerization reaction, but on the other hand in Examples 11, 12, and 14 where a radical generator which is liquid at ordinary temperature was used, some foams could be observed in the resin film after the polymerization reaction. Further, in Examples 1 to 10, 12, and 14 where a support film comprised of a mold release PET film or polyimide film was used, the support film could be peeled off particularly well, but on the other hand in Examples 11 and 13 where PET film not treated for mold release was used, the peel strength of the support film was high and when raising the peel speed, transfer of resin film to the support film was seen, the surface of the resin film after peeling was roughened, and the peelability was otherwise somewhat inferior.

1. A laminate for, forming a resin insulating layer of a built-up board, comprising
a support film, and a resin film which is formed on the support film by using a resin composition containing a radical polymerizable compound,
wherein the resin film is laminated, while maintained in a state where the resin film is laminated on the support film, on a base member constituting the built-up board in a state contacting the base member and is polymerized to thereby form a resin insulating layer of the built-up board.

2. The laminate according to claim 1, wherein the resin composition further contains a radical generator which is solid at ordinary temperature.

3. The laminate according to claim 2, wherein the radical generator has a one-minute half life temperature of 100° C. or more.

4. The laminate according to claim 1, wherein the radical polymerizable compound is a polyfunctional radical polymerizable compound having two or more vinyl groups at a molecule end and/or side chain.

5. The laminate according to claim 1, wherein an oxygen transmission rate of the support film at 20° C. under a dry condition is 2500 (cc/m²/hr/atm) or less.

6. The laminate according to claim 1, wherein
the support film has a mold release layer at its surface and the resin film is formed on a surface of the support film where the mold release layer is formed.

7. A method of production of a built-up board comprising:
preparing a laminate comprising a support film and a resin film which is formed on the support film by using a resin composition containing a radical polymerizable compound; and
laminating the laminate, while the resin film is maintained in a state where the resin film is laminated on the support film, on a base member constituting the built-up board in a state contacting the base member and polymerizing the resin film to thereby form a resin insulating layer.
